(19) United States
(12) Patent Application Publication
(10) Pub. No.: US 2024/0179894 A1
(43) Pub. Date: May 30, 2024

(54) METAL SENSE LINE CONTACT

(71) Applicant: Micron Technology, Inc., Boise, ID (US)

(72) Inventor: Ping Chieh Chiang, Boise, ID (US)

(21) Appl. No.: 18/499,871

(22) Filed: Nov. 1, 2023

Related U.S. Application Data
(60) Provisional application No. 63/428,547, filed on Nov. 29, 2022.

(51) Int. Cl. H10B 12/00; H01L 29/40; H01L 29/49

(52) U.S. Cl. CPC H10B 12/488; H01L 29/401; H01L 29/49; H10B 12/02

(57) ABSTRACT

Methods, apparatuses, and systems related to a metal sense line contact are described. An example apparatus includes a sense line pillar comprising a barrier material over a semiconductor substrate. The sense line pillar further includes a liner material adjacent the barrier material. The sense line pillar further includes a first metal material over the barrier material. The sense line pillar further includes a second metal material over the first metal material. The sense line pillar further includes a cap material over the second metal material. The apparatus further cell contacts between a plurality of sense line pillars.

### PRIORITY INFORMATION

This application claims the benefit of U.S. Provisional Application No. 63/428,547, filed on Nov. 29, 2022, the contents of which are incorporated herein by reference.

### TECHNICAL FIELD

The present disclosure relates generally to semiconductor devices and methods, and more particularly to a metal sense line contact.

### BACKGROUND

Memory devices are typically provided as internal, semiconductor, integrated circuits in computers or other electronic devices. There are many different types of memory, including random-access memory (RAM), read only memory (ROM), dynamic random access memory (DRAM), static random access memory (SRAM), synchronous dynamic random access memory (SDRAM), ferroelectric random access memory (FeRAM), magnetic random access memory (MRAM), resistive random access memory (ReRAM), and flash memory, among others. Some types of memory devices may be non-volatile memory (e.g., ReRAM) and may be used for a wide range of electronic applications in need of high memory densities, high reliability, and low power consumption. Volatile memory cells (e.g., DRAM cells) require power to retain their stored data state (e.g., via a refresh process), as opposed to non-volatile memory cells (e.g., flash memory cells), which retain their stored state in the absence of power. However, various volatile memory cells, such as DRAM cells may be operated (e.g., programmed, read, erased, etc.) faster than various non-volatile memory cells, such as flash memory cells.

### BRIEF DESCRIPTION OF THE DRAWINGS

FIG. 1 illustrates an example cross-sectional side view of a memory cell in accordance with a number of embodiments of the present disclosure.

FIGS. 2A-2F illustrate a cross-sectional view of a portion of semiconductor structure of a memory device in examples of a semiconductor fabrication sequence for a metal sense line contact in accordance with a number of examples of the present disclosure.

FIG. 3 illustrates a cross-sectional view of a portion of the semiconductor structure of a memory device having completed the semiconductor fabrication sequence for a metal sense line contact in accordance with a number of examples of the present disclosure.

FIG. 4 is a functional block diagram of a computing system for implementation of an example semiconductor fabrication process in accordance with a number of embodiments of the present disclosure.

FIG. 5 is a functional block diagram of a computing system including at least one memory array having memory cells formed in accordance with a number of embodiments of the present disclosure.

### DETAILED DESCRIPTION

Various types of semiconductor structures on memory devices (e.g., those that include volatile or non-volatile memory cells) may include rectilinear trenches and/or round, square, oblong, etc., cavities that may be formed into semiconductor material to create openings thereon for subsequent semiconductor processing steps. Various materials may be deposited using chemical vapor deposition (CVD), plasma deposition, etc. and patterned using photolithographic techniques, doped and etched using vapor, wet and/or dry etch processes to form semiconductor structures on a working surface. Such openings may contain, or be associated with, various materials that contribute to data access, storage, and/or processing, or to various support structures, on the memory device. As an example, sense line contacts (e.g., bit line contacts) may be deposited into these openings to provide the data access, storage, and/or processing.

As semiconductor structures increase in height with pillars having higher aspect ratios, there is a decrease in the space between the structures. Subsequent etches to straighten the high aspect ratio pillars may increase the risk of tapering at the bottom of the pillar, leading to an increase in the risk of bending, wobbling, and possible shorts. Previous approaches have typically placed polysilicon as the contact to the digit line material and the cell contacts. As design rules shrink and DRAM devices scale smaller, there is a challenge to decrease the sense line contact resistivity and replace the polysilicon material within the sense contact pillar.

In order to improve the conductivity of a cell of the memory device and decrease sense line contact resistivity, the polysilicon material is replaced with a metal material to connect to the metal material of the digit line to a damascene sense contact material. By connecting the metal material of the sense line contact to the metal material of the digit line, sense line contact resistivity may be decreased.

The present disclosure includes methods, apparatuses, and systems related to a metal sense line contact. As an example, a sense line pillar may comprise a barrier material over a semiconductor substrate. The sense line pillar may also include a liner material adjacent the barrier material. The sense line pillar may also include a first metal material over the barrier material. The sense line pillar may also include a second metal material over the first metal material. The sense line pillar may also include a cap material over the second metal material.

In the following detailed description of the present disclosure, reference is made to the accompanying drawings that form a part hereof, and in which is shown by way of illustration how one or more examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the present disclosure. As used herein, “a number of” something can refer to one or more such things. For example, a number of capacitors can refer to at least one capacitor.

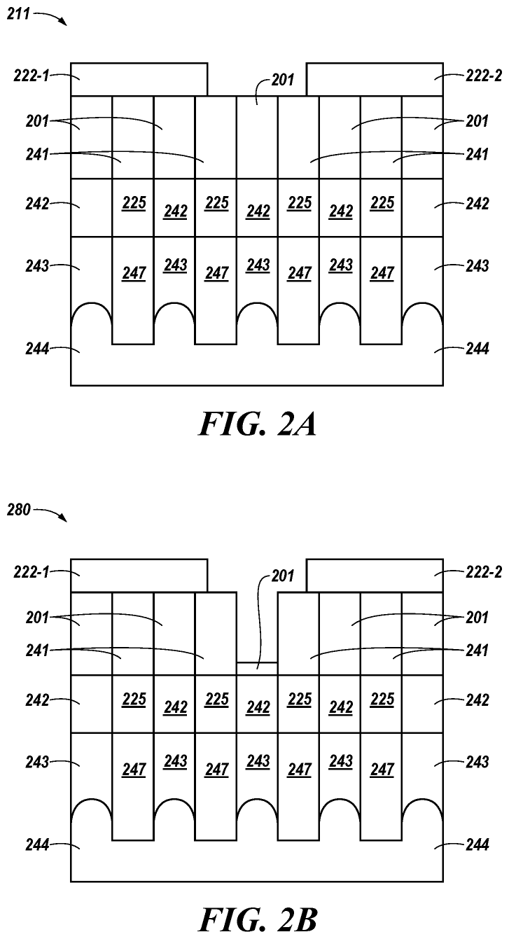

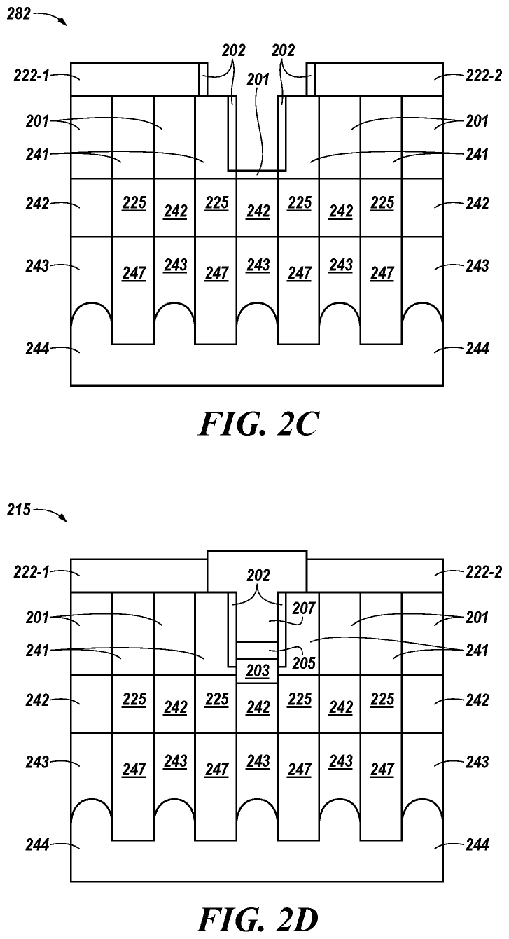

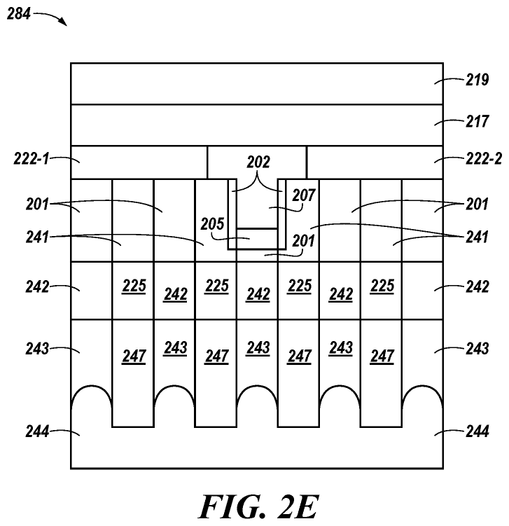

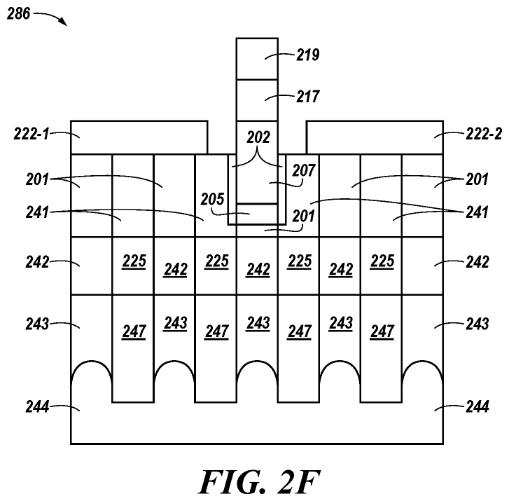

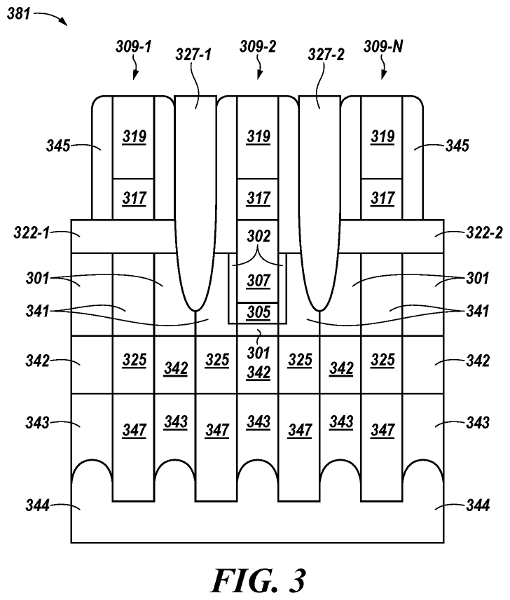

The figures herein follow a numbering convention in which the first digit or digits correspond to the figure number of the drawing and the remaining digits identify an element or component in the drawing. Similar elements or components between different figures may be identified by the use of similar digits. For example, reference numeral 201 may reference element “01” in FIG. 2, and a similar element may be referenced as 303 in FIG. 3. In some instances, a plurality of similar, but functionally and/or structurally distinguishable, elements or components in the same figure or in different figures may be referenced sequentially with the same element number (e.g., 309-1, 309-2, 309-3 in FIG. 3).

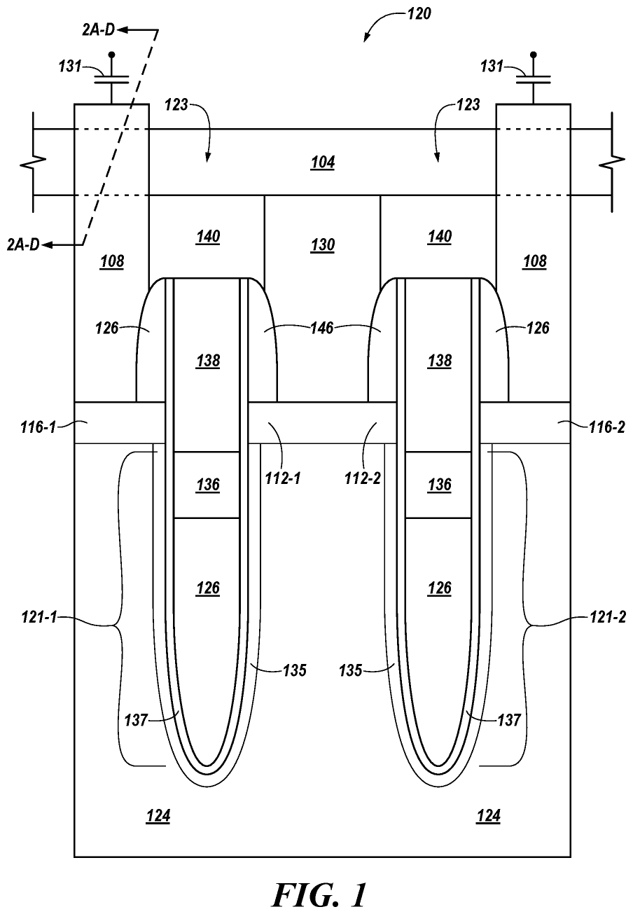

FIG. 1 illustrates a cross-sectional view 100 of an apparatus 120 showing a pair of neighboring memory cells sharing a source/drain region, e.g., 112-1 and 112-2, and a sense line contact 130 connecting to a passing sense line 104. The pair of neighboring memory cells include access devices 123-1, 123-2 (hereinafter referred to individually or collectively as access devices 123) coupled to storage node contacts 108-1, 108-2 (hereinafter referred to individually or collectively as storage note contacts 108) and storage nodes 131-1, 131-2 (hereinafter referred to individually or collectively as storage nodes 131) in accordance with a number of embodiments of the present disclosure.

The access devices 123 include gates 121-1, 121-2, individually or collectively referred to as gates 121. The gates 121 may also be referred to as a gate electrode. The access devices 123 may include recessed access devices, e.g., a buried recessed access device (BRAD). In the example shown, the gate 121 may include a first portion 126 including a metal containing material, e.g., titanium nitride (TiN), and a second portion 136 including a doped polysilicon to form a hybrid metal gate (HMG) 121. The gate 121 may be separated from a channel 135 by a gate dielectric 137. The gate 121 separates a first source/drain region 116-1 and 116-2, collectively referred to as first source/drain region 116, and a second source/drain region 112-1 and 112-2, collectively referred to as second source/drain region 112. In the example of FIG. 1, two neighboring access devices 123 are shown sharing a second source/drain region 112 at a junction. The neighboring access devices 123 may be formed on a working surface of a semiconductor material on a substrate 124.

In the example of FIG. 1, a storage node 131 (shown schematically for ease of illustration) is connected to a storage node contact 108 formed in accordance with the techniques described herein. The storage node contact 108 may be connected to an active area, e.g., a first source/drain region 116 of an access device 123. An insulation material 140 (e.g., a dielectric material) may be formed on the spacer material 146 and the gate mask material 138, and in contact with a conductive material 130 serving as a sense line contact 130. The sense line contact 130 may be connected to a sense line 104, e.g., passing sense line orthogonal to a directional orientation of access lines connecting to gates 121 of the access devices 123. In the example illustration of FIG. 1, the illustrated passing sense line 104 is actually recessed into the page, parallel to the plane of the drawing sheet so as to be offset a particular depth from the storage nodes 131. Access lines connected to gates 121 may be running perpendicular to a plane of the drawing sheet, e.g., coming out of the page.

In some embodiments the sense line contact 130 may be a metallic material, e.g., Tungsten (W). The insulation material 140 may be formed on the spacer material 146 and the gate mask material 138, and in contact with the conductive sense line material 130. In the embodiments described below, FIGS. 2A-3 illustrate a metal sense line (metal material 207 and metal material 307 in FIGS. 2A-2F and 3 respectively) with a metal digit line material (second metal material 217 and second metal material 317 in FIGS. 2A-2F and 3 respectively) formed on top. The combination of the metal sense line and the metal digit line material to create a damascene sense contact material. By connecting the metal material of the sense line contact to the metal material of the digit line, sense line contact resistivity may be decreased.

FIG. 2A illustrates a cross-sectional view 211 of a portion of a semiconductor structure of a memory device in association with a semiconductor fabrication sequence for a metal sense line contact in accordance with a number of examples of the present disclosure.

The example memory device can include a plurality of sense line pillars (fully developed as plurality of sense line pillars 309 in FIG. 3). Each of the plurality of sense line pillars may include an underlying substrate material 201.

The substrate material 201 may be formed from various undoped or doped materials on which memory device materials may be fabricated. Examples of a relatively inert undoped substrate material 201 may include monocrystalline silicon (monosilicon), polycrystalline silicon (polysilicon), and amorphous silicon, among other possibilities. The substrate material 201 may also be formed from an oxide material selected for dielectric properties.

As shown in the example embodiment of FIG. 2A, the semiconductor structure of the memory device may include an interlayer dielectric (ILD) material 222-1 and 222-2 (hereinafter referred to collectively as ILD material 222) that may be formed extending in a horizontal direction, as illustrated, adjacent and above the substrate material 201. The ILD material 222 may be etched for the formation of the sense line pillars. The ILD material 222 may include an insulating material, e.g., dielectric material, such as, for example, one of an oxide material, silicon oxide (SiO₂) material, silicon nitride (SiN) material, silicon oxynitride material, and/or combination thereof, etc. The semiconductor structure of the memory device may also include a silicon substrate material 244, a polysilicon word line material 243, a metal word line material 242, and a nitride shallow trench isolation fill material 241, a polysilicon material 225, and a nitride (e.g., Titanium nitride (TiN)) material 247.

FIG. 2B illustrates a cross-sectional view 280 of a portion of semiconductor structure of a memory device in an example of a semiconductor fabrication sequence for a metal sense line contact in accordance with a number of examples of the present disclosure. FIG. 2B illustrates the example semiconductor structure at a particular stage following completion of the example fabrication sequence described in connection with FIG. 2A.

An etch process (e.g., a first wet etch process or dry etch process) may be utilized to etch the substrate material 201 vertically down to a lower height more suitable to create the sense line contacts. The etchant material may be selective only to the substrate material 201 such that the ILD material 222 is not affected by the etchant material.

FIG. 2C illustrates a cross-sectional view 282 of a portion of semiconductor structure of a memory device in another example of a semiconductor fabrication sequence for a metal sense line contact in accordance with a number of examples of the present disclosure.

The plurality of sense line pillars (fully developed as plurality of sense line pillars 309 in FIG. 3) may include a liner material 202. The liner material 202 may be formed on the sidewalls of the plurality of sense line pillars. The substrate material 201 may be selectively etched prior to forming the liner material 202. The liner material 202 may, in a number of examples, have been formed from a polycrystalline silicon (polysilicon) material. The silicon compound may be silicon dioxide (SiO₂), which may be formed by oxidation of silane (SiH₄), among other possibilities. The silicon compound may also include monocrystalline silicon (monosilicon) and amorphous silicon, among other possibilities. The liner material 202 may be undoped except as needed to connect with the sense line contact. In other examples, the liner material 202 may be formed from a nitride material.

FIG. 2D illustrates a cross-sectional view 215 of a portion of semiconductor structure of a memory device in another example of a semiconductor fabrication sequence for a metal sense line contact in accordance with a number of examples of the present disclosure. FIG. 2D illustrates the example semiconductor structure at a particular stage following completion of the example fabrication sequence described in connection with FIG. 2C.

A silicate material may be formed (e.g., deposited) over the semiconductor substrate material 201, adjacent the liner material 202. The silicate material may be a polysilicon material 203 and in a number of examples, have been formed from a polycrystalline silicon (polysilicon). The silicon compound may be silicon dioxide (SiO₂), which may be formed by oxidation of silane (SiH₄), among other possibilities. The silicon compound may also include monocrystalline silicon (monosilicon) and amorphous silicon, among other possibilities. The polysilicon material 303 may be undoped except as needed to connect with the sense line contact.

A barrier material 205 may be formed over a surface of the polysilicon material 203 opposite from the substrate material 201. The barrier material 205 may be surrounded by the liner material 202. The barrier material 205 may be formed from a metal material. The barrier material 205 may be formed from a titanium (Ti) material. The titanium (Ti) material may be a titanium silicide (TiSix) material. The barrier material 205 may also be formed from transition metals such as tungsten (W), rhenium (Re), osmium (Os), iridium (Ir), platinum (Pt), titanium (Ti), zirconium (Zr), chromium (Cr), ruthenium (Ru), and palladium (Pd), among other possibilities.

A metal material 207 may be formed over a surface of the barrier material 205 opposite from the polysilicon material 203. The metal material 207 may be formed (e.g., deposited) over an upper surface of the barrier material 205. The metal material 207 may also be formed vertically adjacent the liner material 202 and horizontally adjacent the ILD material 222. The metal material 207 may serve as a sense line contact for the plurality of sense line pillars (fully developed as plurality of sense line pillars 309 in FIG. 3). The metal material 207 may be formed from a metal material selected for conductive properties. The metal material 207 may be formed from a titanium (Ti) material. The titanium (Ti) material may be a titanium nitride (TiN) material. The metal material 207 may also be formed from materials similar to the barrier material 205. The metal material 207 may be formed from transition metals such as tungsten (W), rhenium (Re), osmium (Os), iridium (Ir), platinum (Pt), titanium (Ti), zirconium (Zr), chromium (Cr), ruthenium (Ru), and palladium (Pd), among other possibilities.

An etch process (e.g., a first wet etch process or dry etch process) may be utilized to selectively etch away the polysilicon material 203 such that the barrier material 205 is over the substrate material 201. The etchant material may be selective only to the polysilicon material 203 such that the liner material 202, the barrier material 205, the metal material 207 and the ILD material 222 are not affected by the etchant material.

FIG. 2E illustrates a cross-sectional view 284 of a portion of semiconductor structure of a memory device in another example of a semiconductor fabrication sequence for a metal sense line contact in accordance with a number of examples of the present disclosure. FIG. 2E illustrates the example semiconductor structure at a particular stage following completion of the example fabrication sequence described in connection with FIG. 2D.

A second metal material 217 may be formed over the metal material 207 and ILD material 222. The second metal material 217 may be a digit line metal material. The second metal material 217 may be formed from a metal material selected for conductive properties. The second metal material 217 may be formed from a tungsten (W) material. The second metal material 217 may also be formed from materials similar to the metal material 207. The second metal material 217 may be formed from transition metals such as titanium (Ti), rhenium (Re), osmium (Os), iridium (Ir), platinum (Pt), titanium (Ti), zirconium (Zr), chromium (Cr), ruthenium (Ru), and palladium (Pd), among other possibilities.

Previous approaches may have placed polysilicon as the connect to the digit line material and the cell contacts. As semiconductor structures increase in height with pillars having higher aspect ratios, there is a decrease in the space between the structures. Subsequent etches to straighten the high aspect ratio pillars may increase the risk of tapering at the bottom of the pillar, leading to an increase in the risk of bending, wobbling, and possible shorts. In order to decrease sense line contact resistivity, the polysilicon material is replaced with a metal material to connect to the metal material of the digit line. By forming the second metal material 217 over the metal material 207, sense line contact resistivity may be decreased. The resistivity of the sense line pillars may be reduced to being 6 ohms (2) or less.

A cap material 219 may be formed above the second metal material 217 opposite the metal material 207 and the ILD material 222. The cap material 219 may be a nitride material. The cap material 219 may be formed from a nitride material selected for dielectric properties. For example, one or more dielectric and/or resistor nitrides may be selected from boron nitride (BN), silicon nitride (SiNX, Si3N4), aluminum nitride (AlN), gallium nitride (GN), tantalum nitride (TaN, Ta2N), titanium nitride (TIN, Ti2N), and tungsten nitride (WN, W2N, WN2), among other possibilities.

FIG. 2F illustrates a cross-sectional view 286 of a portion of semiconductor structure of a memory device in another example of a semiconductor fabrication sequence for a metal sense line contact in accordance with a number of examples of the present disclosure. FIG. 2F illustrates the example semiconductor structure at a particular stage following completion of the example fabrication sequence described in connection with FIG. 2E.

An etch process (e.g., a first wet etch process or dry etch process) may be utilized to etch away portions of the cap material 219, the second metal material 217, the metal material 207, the ILD material 222, the barrier material 205, and the liner material 202, resulting in a pillar. This etch process may etch the materials that will form the plurality of sense line pillars. The width of the materials of the plurality of sense line pillars after the etch process may be a range between 5-9 nanometers (nm).

FIG. 3 illustrates a cross-sectional view 381 of a portion of semiconductor structure of a memory device having completed the semiconductor fabrication sequence for a metal sense line contact in accordance with a number of examples of the present disclosure. FIG. 3 illustrates the example semiconductor structure at a particular stage following completion of the example fabrication sequence described in connection with FIGS. 2A-2F.

The cross-sectional view 381 can include the same or similar elements as the example cross-sectional views 211, 280, 282, 215, 284, and 286 as referenced in FIGS. 2A-2F respectively. For example, the substrate 301 is analogous or similar to substrate material 201 of FIGS. 2A-2F. The liner material 302 is analogous or similar to liner 202 of FIG. 2C-2F. The barrier material 305 is analogous or similar to barrier material 205 of 2D-2F. The metal material 307 is analogous or similar to metal material 207 of FIGS. 2D-2F. The ILD material 322 is analogous or similar to ILD material 222 of FIGS. 2A-2F. The digit line metal material 317 is analogous or similar to digit line metal material 217 of FIGS. 2E-2F. The cap material 319 is analogous or similar to cap material 219 of FIGS. 2E-2F. The silicon substrate material 344 is analogous or similar to silicon substrate material 244 of FIGS. 2A-2F. The polysilicon word line material 343 is analogous or similar to polysilicon word line material 243 of FIGS. 2A-2F. The polysilicon material 325 is analogous or similar to the polysilicon material 225 of FIGS. 2A-2F. The nitride material (e.g., TiN material) 347 is analogous or similar to the nitride material (e.g., TiN material) 247 of FIGS. 2A-2F. The metal word line material 342 is analogous or similar to metal word line material 242 of FIGS. 2A-2F. The nitride shallow trench isolation fill material 341 is analogous or similar to nitride shallow trench isolation fill material 241 of FIGS. 2A-2F.

The etching away of the ILD material 322 in FIG. 3C may create an opening for forming cell contacts 327-1 and 327-2 (hereinafter referred to collectively as cell contacts 327) through the ILD material 322-1 and 322-2. As such, the cell contacts 327 may be formed (e.g., deposited) between the plurality of sense line pillars 309-1, 309-2, . . . , 309-N (hereinafter referred to collectively as plurality of sense line pillars 309) and adjacent the liner material 302 in FIG. 2F. The plurality of sense line pillars 309 may include substrate material 301, liner material 302, barrier material 305, metal material 307, digit line metal material 317, and cap material 319. A spacer material 345 may also be deposited between each sense line pillar and the cell contact 327.

The cell contacts 327 may be formed from a silicate material. The cell contacts 327 may, in a number of examples, have been formed from a polycrystalline silicon (polysilicon) material. The silicon compound may be silicon dioxide (SiO₂), which may be formed by oxidation of silane (SiH₄), among other possibilities. The silicon compound may also include monocrystalline silicon (monosilicon) and amorphous silicon, among other possibilities. The cell contacts 327 may be undoped except as needed to connect with the sense line contact. Although only two cell contacts are illustrated, embodiments are not so limited.

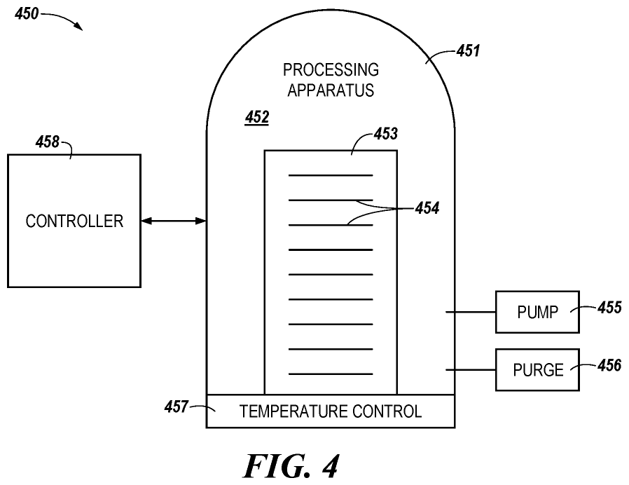

FIG. 4 illustrates an example processing apparatus 451 that may be used in a semiconductor fabrication process within a system 450. The processing apparatus 451 may include a chamber 452 to enclose components configured to perform deposition and/or etch operations on a number of semiconductor devices. The chamber 452 may further enclose a carrier 453 to hold a batch of semiconductor wafers 454. The processing apparatus 451 may include and/or be associated with tools including, for example, a pump 455 unit and a purge 456 unit configured to introduce and remove appropriate etch chemistries, as described herein, at each point in the semiconductor fabrication sequence. The processing apparatus 451 may further include a temperature control 457 unit configured to maintain the chamber 452 at an appropriate temperature at each of the points in the fabrication sequence. The system 450 may include a number of chambers 452 that are each configured to perform particular processes (e.g., a wet etch process, a dry etch process, and/or a deposition process, among others) during the fabrication sequence.

The system 450 may further include a controller 458. The controller 458 may include, or be associated with, circuitry and/or programming for implementation of, for instance, formation of a metal sense line contact. The material may be grown to a size that seals the non-solid space adjacent the storage node contact. Adjustment of such deposition, removal, and etching operations by the controller 458 may control the critical dimensions (CDs) of the semiconductor devices created in the processing apparatus 451.

A host may be configured to generate instructions related to formation of a metal sense line contact. The instructions may be sent via a host interface to the controller 458 of the processing apparatus 451. The instructions may be based at least in part on scaled preferences (e.g., in numerically and/or structurally defined gradients) stored by the host, provided via input from another storage system (not shown), and/or provided via input from a user (e.g., a human operator), among other possibilities. The controller 458 may be configured to enable input of the instructions and scaled preferences to define the CDs of the fabrication of the semiconductor device to be implemented by the processing apparatus 451.

The scaled preferences may determine final structures (e.g., the CDs) of passing sense lines and storage node contact. Particular CDs may be enabled by the particular scaled preferences that are input via the instructions. Receipt and implementation of the scaled preferences by the controller 458 may result in corresponding adjustment, by the processing apparatus 451, of a deposition time for the formation of a metal sense line contact, adjustment of a coverage area, height, and/or volume of the metal sense line contact, among implementation of other possible scaled preferences.

The controller 458 may, in a number of embodiments, be configured to use hardware as control circuitry. Such control circuitry may, for example, be an application specific integrated circuit (ASIC) with logic to control fabrication steps, via associated deposition and etch processes. The controller 458 may be configured to receive the instructions and direct performance of operations to form a metal sense line contact as described in connection with FIG. 1-3.

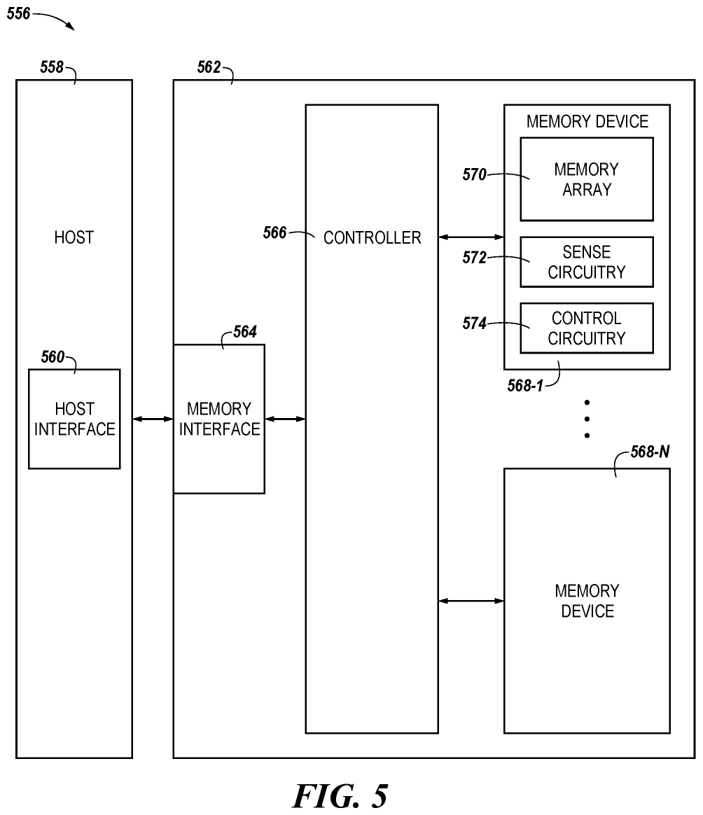

FIG. 5 is a functional block diagram of a computing system 556 including at least one memory system 562 in accordance with one or more embodiments of the present disclosure. The numbering convention used in connection with FIG. 5 does not follow the earlier introduced numbering convention and sequence that applies to FIGS. 1-3. Memory system 562 may be, for example, a solid-state drive (SSD).

In the embodiment illustrated in FIG. 5, memory system 562 includes a memory interface 564, a number of memory devices 568-1, . . . , 568-N, and a controller 566 selectably coupled to the memory interface 564 and memory devices 568-1, . . . , 568-N. Memory interface 564 may be used to communicate information between memory system 562 and another device, such as a host 558. Host 558 may include a processor (not shown). As used herein, “a processor” may be a number of processors, such as a parallel processing system, a number of coprocessors, etc. Example hosts may include, or by implemented in, laptop computers, personal computers, digital cameras, digital recording devices and playback devices, mobile telephones, PDAs, memory card readers, interface hubs, and the like. Such a host 558 may be associated with fabrication operations performed on semiconductor devices and/or SSDs using, for example, a processing apparatus shown at 551 and described in connection with FIG. 5.

In a number of embodiments, host 558 may be associated with (e.g., include or be coupled to) a host interface 560. The host interface 560 may enable input of scaled preferences (e.g., in numerically and/or structurally defined gradients) to define, for example, critical dimensions (CDs) of a final structure or intermediary structures of a memory device (e.g., as shown at 568) and/or an array of memory cells (e.g., as shown at 570) formed thereon to be implemented by the processing apparatus 551. The array includes access devices having metal sense line contacts according to embodiments described herein. The scaled preferences may be provided to the host interface 560 via input of a number of preferences stored by the host 558, input of preferences from another storage system (not shown), and/or input of preferences by a user (e.g., a human operator).

Memory interface 564 may be in the form of a standardized physical interface. For example, when memory system 562 is used for information (e.g., data) storage in computing system 556, memory interface 564 may be a serial advanced technology attachment (SATA) interface, a peripheral component interconnect express (PCIe) interface, or a universal serial bus (USB) interface, among other physical connectors and/or interfaces. In general, however, memory interface 564 may provide an interface for passing control, address, information, scaled preferences, and/or other signals between the controller 566 of memory system 562 and a host 558 (e.g., via host interface 560).

Controller 566 may include, for example, firmware and/or control circuitry (e.g., hardware). Controller 566 may be operably coupled to and/or included on the same physical device (e.g., a die) as one or more of the memory devices 568-1, . . . , 568-N. For example, controller 566 may be, or may include, an ASIC as hardware operably coupled to circuitry (e.g., a printed circuit board) including memory interface 564 and memory devices 568-1, . . . , 568-N. Alternatively, controller 566 may be included on a separate physical device that is communicatively coupled to the physical device (e.g., the die) that includes one or more of the memory devices 568-1, . . . , 568-N.

Controller 566 may communicate with memory devices 568-1, . . . , 568-N to direct operations to sense (e.g., read), program (e.g., write), and/or erase information, among other functions and/or operations for management of memory cells. Controller 566 may have circuitry that may include a number of integrated circuits and/or discrete components. In a number of embodiments, the circuitry in controller 566 may include control circuitry for controlling access across memory devices 568-1, . . . , 568-N and/or circuitry for providing a translation layer between host 558 and memory system 562.

Memory devices 568-1, . . . , 568-N may include, for example, a number of memory arrays 570 (e.g., arrays of volatile and/or non-volatile memory cells). For instance, memory devices 568-1, . . . , 568-N may include arrays of memory cells, such as a portion of an example memory device structured to include storage node contacts. At least one array includes an access device having a storage node contact formed according to the embodiments disclosed herein. As will be appreciated, the memory cells in the memory arrays 570 of memory devices 568-1, . . . , 568-N may be in a RAM architecture (e.g., DRAM, SRAM, SDRAM, FeRAM, MRAM, ReRAM, etc.), a flash architecture (e.g., NAND, NOR, etc.), a three-dimensional (3D) RAM and/or flash memory cell architecture, or some other memory array architecture including pillars and adjacent trenches.

Memory device 568 may be formed on the same die. A memory device (e.g., memory device 568-1) may include one or more arrays 570 of memory cells formed on the die. A memory device may include sense circuitry 572 and control circuitry 574 associated with one or more arrays 570 formed on the die, or portions thereof. The sense circuitry 572 may be utilized to determine (sense) a particular data value (e.g., 0 or 1) that is stored at a particular memory cell in a row of an array 570. The control circuitry 574 may be utilized to direct the sense circuitry 572 to sense particular data values, in addition to directing storage, erasure, etc., of data values in response to a command from host 558 and/or host interface 560. The command may be sent directly to the control circuitry 574 via the memory interface 564 or to the control circuitry 574 via the controller 566.

The embodiment illustrated in FIG. 5 may include additional circuitry that is not illustrated so as not to obscure embodiments of the present disclosure. For example, memory device 568 may include address circuitry to latch address signals provided over I/O connectors through I/O circuitry. Address signals may be received and decoded by a row decoder and a column decoder to access a memory array 570. It will be appreciated that the number of address input connectors may depend on the density and/or architecture of memory devices 568 and/or memory arrays 570.

In the above detailed description of the present disclosure, reference is made to the accompanying drawings that form a part hereof, and in which is shown by way of illustration how one or more examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the present disclosure.

It is to be understood that the terminology used herein is for the purpose of describing particular examples only and is not intended to be limiting. As used herein, the singular forms “a”, “an”, and “the” include singular and plural referents, unless the context clearly dictates otherwise, as do “a number of”, “at least one”, and “one or more” (e.g., a number of memory arrays may refer to one or more memory arrays), whereas a “plurality of” is intended to refer to more than one of such things. Furthermore, the words “can” and “may” are used throughout this application in a permissive sense (i.e., having the potential to, being able to), not in a mandatory sense (i.e., must). The term “include,” and derivations thereof, means “including, but not limited to”. The terms “coupled” and “coupling” mean to be directly or indirectly connected physically and, unless stated otherwise, can include a wireless connection for access to and/or for movement (transmission) of instructions (e.g., control signals, address signals, etc.) and data, as appropriate to the context.

While example examples including various combinations and configurations of semiconductor materials, underlying materials, structural materials, dielectric materials, capacitor materials, working surface materials, silicate materials, nitride materials, buffer materials, etch chemistries, etch processes, solvents, memory devices, memory cells, sidewalls of openings and/or trenches, among other materials and/or components related to formation of a metal sense line contact have been illustrated and described herein, examples of the present disclosure are not limited to those combinations explicitly recited herein. Other combinations and configurations of the semiconductor materials, underlying materials, structural materials, dielectric materials, capacitor materials, substrate materials, working surfaces, silicate materials, nitride materials, buffer materials, etch chemistries, etch processes, solvents, memory devices, memory cells, sidewalls of openings and/or trenches related formation of a metal sense line contact than those disclosed herein are expressly included within the scope of this disclosure.

Although specific examples have been illustrated and described herein, those of ordinary skill in the art will appreciate that an arrangement calculated to achieve the same results may be substituted for the specific examples shown. This disclosure is intended to cover adaptations or variations of one or more examples of the present disclosure. It is to be understood that the above description has been made in an illustrative fashion, and not a restrictive one. Combination of the above examples, and other examples not specifically described herein will be apparent to those of skill in the art upon reviewing the above description. The scope of the one or more examples of the present disclosure includes other applications in which the above structures and processes are used. Therefore, the scope of one or more examples of the present disclosure should be determined with reference to the appended claims, along with the full range of equivalents to which such claims are entitled.

In the foregoing Detailed Description, some features are grouped together in an example for the purpose of streamlining the disclosure. This method of disclosure is not to be interpreted as reflecting an intention that the disclosed examples of the present disclosure have to use more features than are expressly recited in each claim. Rather, as the following claims reflect, inventive subject matter lies in less than all features of a disclosed example. Thus, the following claims are hereby incorporated into the Detailed Description, with each claim standing on its own as a separate example.

What is claimed is:

1. An apparatus, comprising:
a sense line pillar, comprising:
a barrier material over a semiconductor substrate;
a liner material adjacent the barrier material;
a first metal material as a sense line contact over the barrier material;
a second metal material over the first metal material; and
a cap material over the second metal material; and
cell contacts between a plurality of sense line pillars.

2. The apparatus of claim 1, wherein the second metal material and the first metal material reduce resistivity of the sense line pillar to less than 6 ohms (Ω).

3. The apparatus of claim 1, wherein the second metal material is a digit line.

4. The apparatus of claim 1, wherein the first metal material is a titanium nitride (TiN) material.

5. The apparatus of claim 1, wherein the cell contacts are a polysilicon material.

6. The apparatus of claim 1, wherein the liner material is a nitride material.

7. An apparatus, comprising:
a sense line pillar, comprising:
a barrier material over a semiconductor substrate;
a nitride material adjacent the barrier material;
a titanium nitride (TiN) material over the barrier material;
a digit line metal material over the first metal material; and
a cap material over the second metal material; and
cell contacts between a plurality of sense line pillars.

8. The apparatus of claim 7, further comprising a liner material around the barrier material and adjacent the cell contacts.

9. The apparatus of claim 8, wherein the liner material is a polysilicon material.

10. The apparatus of claim 7, wherein the cap material is a nitride material.

11. The apparatus of claim 7, wherein a width for the plurality of sense line pillars is in a range between 5-9 nanometers (nm).

12. The apparatus of claim 7, wherein the barrier material is a titanium silicide (TiSix) material.

13. The apparatus of claim 7, wherein the digit line metal material is a tungsten material.

14. The apparatus of claim 7, wherein the semiconductor substrate is a silicon material.

15. A method, comprising:
etching an interlayer dielectric material within a semiconductor structure;
etching a silicon material within the semiconductor structure to create a substrate material;
patterning a sense line pillar, comprising:
forming a liner material on the sidewalls of the semiconductor structure;
forming a polysilicon material over the semiconductor substrate adjacent the liner material;
forming a barrier material over the polysilicon material;
forming a metal material over the barrier material;
forming a digit line metal material over the metal material; and
forming a cap material over the digit line metal material; and
forming cell contacts between a plurality of sense line pillars.

16. The method of claim 13, further comprising forming the digit line metal material over the metal material decreases sense line contact resistivity of the plurality of sense line pillars.

17. The method of claim 13, further comprising etching the semiconductor substrate prior to forming the liner material on the sidewalls.

18. The method of claim 13, further comprising selectively etching the polysilicon material prior to forming the digit line metal material.

19. The method of claim 13, further comprising forming a dielectric material adjacent the metal material.

20. The method of claim 19, further comprising etching the dielectric material, the metal material, digit line metal material and the cap material prior to forming the cell contacts.
